(19) United States
(12) Patent Application Publication
(10) Pub. No.: US 2010/0258786 A1
(43) Pub. Date: Oct. 14, 2010

(54) SELF-ASSEMBLED ORGANIC MONOLAYERS ON GRAPHENE AND METHODS OF MAKING AND USING

(75) Inventors: Qing Hua WANG, Evanston, IL (US); Mark C. Hersam, Evanston, IL (US)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: NORTHWESTERN UNIVERSITY, Evanston, IL (US)

(21) Appl. No.: 12/753,942

(22) Filed: Apr. 5, 2010

Related U.S. Application Data
(60) Provisional application No. 61/168,010, filed on Apr. 9, 2009.

(51) Int. Cl. H01L 51/30; H01L 51/40

(52) U.S. Cl. 257/29; 438/99; 977/734; 257/40; 257/77; 257/E51.024

(57) ABSTRACT

Self-assembled organic monolayers on epitaxial graphene are described. The organic molecules are perylene derivatives including 3,4,9,10-perylene-tetracarboxylic dianhydride (PTCDA) molecules arranged in a herringbone phase and/or molecules are of the following formula:

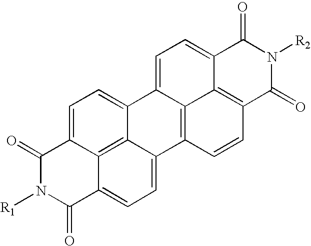

wherein R₁ and R₂ are alkyl groups. The organic monolayers can be patterned. Metal oxides can also be deposited on the organic monolayers. Methods of forming the self-assembled organic monolayers are also described.

### CROSS REFERENCE TO RELATED CASES

This application claims the benefit of Provisional U.S. Application Ser. No. 61/168,010, filed Apr. 9, 2009, which is incorporated by reference herein in its entirety.

### STATEMENT REGARDING FEDERALLY SPONSORED RESEARCH

This invention was made with government support under Grant Nos. EEC-0647560, DMR-0520513 and ECS-0506802 awarded by the National Science Foundation, and Grant Nos. N00014-05-1-0563 and N00014-09-1-0180 awarded by the Office of Naval Research. The government has certain rights in the invention.

### BACKGROUND

1. FIELD

This application relates generally to self assembled organic monolayers on substrates and methods of making and using the same and, in particular, to self-assembled organic monolayers of perylene derivatives on graphene and methods of making and using the same.

2. Background of the Technology

Graphene, a two-dimensional hexagonal lattice of carbon atoms, is an emerging material that has attracted significant attention due to its unique electronic structure, high carrier mobilities, and quantum relativistic phenomena^{l-4}. While many of these properties have been demonstrated on mechanically exfoliated graphene sheets, epitaxial graphene grown on SiC(0001) surfaces⁵⁻⁷ is a promising electronic material because it allows for wafer-scale processing and patterning of devices using traditional lithography^{8,9}. Epitaxial graphene formed by the thermal decomposition of silicon from SiC(0001) above 1200° C. has been studied using a wide variety of spectroscopic¹⁰⁻¹³ and scanning probe¹⁴⁻²⁰ techniques. The structure consists of layers of graphene sheets on top of a carbon-rich interfacial layer known as the (6√3×6√3)R30° reconstruction. The growth mechanism results in a carpet-like coverage of continuous sheets that cover many SiC steps^{15,21}. The presence of the SiC substrate, the interfacial states, and various intrinsic defects²² such as sixfold scattering centers and subsurface carbon nanotubes may influence the electronic and chemical properties of epitaxial graphene.

In order to realize its full potential for a diverse range of devices, the bare graphene sheet must be incorporated with other materials. Some initial progress has been made toward the surface functionalization of graphene. In a recent paper by Wang et al²³, atomic layer deposition of Al₂O₃ was achieved on mechanically exfoliated graphene sheets by functionalizing them with carboxylate-terminated perylene derivatives, while other recent research demonstrated the doping of SiC-grown epitaxial graphene by the deposition of organic molecules²⁴ and metal atoms^{10,11,25,26}. In addition, a recent low temperature scanning tunneling microscopy (STM) study found that 3,4,9,10-perylene-tetracarboxylic dianhydride (PTCDA) forms a monolayer with a brickwall structure on epitaxial graphene on SiC(0001)²⁷. However, this brickwall phase of PTCDA was reported to be unstable as STM imaging could only be accomplished at 4.7 K, which is an impractically low temperature for most applications and subsequent chemistry. Furthermore, the influence of the SiC substrate,

Accordingly, there exists a need for organic monolayers on graphene having improved stability.

### SUMMARY

An article of manufacture is provided which comprises:
an epitaxial graphene layer;
a monolayer of molecules on a surface of the graphene layer;
wherein the molecules are 3,4,9,10-perylene-tetracarboxylic dianhydride (PTCDA) molecules arranged in a herringbone phase and/or wherein the molecules are of the following formula:

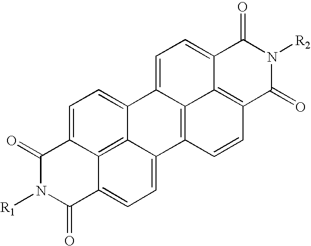

wherein R₁ and R₂ are alkyl groups.

A method is also provided which comprises:
depositing a monolayer of molecules on a surface of an epitaxial graphene layer:
wherein the molecules are 3,4,9,10-perylene-tetracarboxylic dianhydride (PTCDA) molecules arranged in a herringbone phase or wherein the molecules are of the following formula:

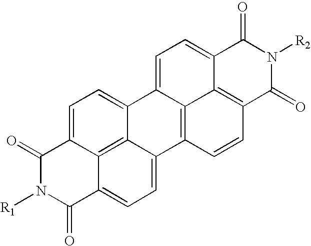

wherein R₁ and R₂ are alkyl groups.

These and other features of the present teachings are set forth herein.

### BRIEF DESCRIPTION OF THE DRAWINGS

The skilled artisan will understand that the drawings, described below, are for illustration purposes only. The drawings are not intended to limit the scope of the present teachings in any way.

FIG. 1a is an STM image of epitaxial graphene grown on SiC(0001) (tunneling parameters: Vₛ=2.0 V, I=0.1 nA) wherein the large terrace in the center of the image is monolayer graphene and wherein various defects are visible.

FIG. 1b is a high resolution STM image of monolayer graphene with the underlying (6√3×6√3)R30° states visible as bright, irregular protrusions (Vₛ=−0.5 V, I=0.05 nA).

FIG. 1c is an atomic resolution STM image of bilayer graphene (Vₛ=0.25 V, I=0.02 nA) wherein the atomic lattice is indicated with the hexagon.

FIG. 1d is an STM image of a loop defect and two six-fold scattering center defects (Vₛ=0.25 V, I=0.02 nA).

FIG. 1e is an STM image of subsurface nanotube defects (Vₛ=−0.3 V, I=0.05 nA).

FIG. 2a is a schematic representing the molecular structure of 3,4,9,10-perylene-tetracarboxylic dianhydride (PTCDA).

FIG. 2b is an STM image showing monolayer coverage of PTCDA on epitaxial graphene.

FIG. 2c is a molecular-resolution STM image of the PTCDA monolayer. PTCDA molecular structure and unit cell outline are overlaid wherein the monolayer continuously follows the graphene sheet over the SiC step edge.

FIG. 2d is a schematic showing the PTCDA herringbone unit cell, with lattice vectors \vec{a} and \vec{b} indicated.

FIG. 2e is an STM image showing PTCDA surrounding a step edge where the graphene sheet is not continuous.

FIG. 2f is an STM image showing PTCDA continuously covers a graphene subsurface nanotube defect.

FIG. 2g is an STM image showing a bright protrusion that does not disrupt the PTCDA monolayer and that is potentially attributed to a six-fold scattering center defect. (Vₛ=−2.0 V, I=0.05 nA for all five STM images).

FIG. 3a is an STM image of a submonolayer coverage of PTCDA on graphene (Vₛ=−2.0 V, I=0.05 nA) wherein the PTCDA island is in the bottom right half of the image while the clean graphene substrate is in the remainder of the image.

FIG. 3b is the same image as FIG. 3a but with the PTCDA island highlighted in blue to aid the eye.

FIG. 3c is a high resolution STM image of a PTCDA island boundary with the atomically resolved graphene substrate on the left half of the image and the PTCDA molecules on the right half (Vₛ=0.25 V, I=0.05 nA).

FIG. 3d is an STM image showing a domain boundary between two PTCDA domains with different orientations (Vₛ=−2.0 V, I=0.05 nA) wherein, within each domain, the direction of the \vec{a} lattice vector is indicated by thin white arrows and wherein the ends of the domain boundary are indicated by large blue arrows.

FIG. 4A is an STM image showing the sample area in which spectroscopy was conducted wherein the upper half of the image is pristine graphene while the lower half is a PTCDA island and wherein the squares indicate areas in which dI/dV spectra were taken at random positions.

FIG. 4B is a graph showing dI/dV vs. V spectra for clean graphene.

FIG. 4C is a graph showing dI/dV vs. V spectra for the PTCDA monolayer (setpoint: Vₛ=1.0 V, I=0.1 nA).

FIG. 5 is room temperature ultra-high vacuum scanning tunneling microscopy image of a self-assembled monolayer of 3,4,9,10-perylene-tetracarboxylic dianhydride (PTCDA) on an epitaxial graphene surface.

FIG. 6A is an STM topography image showing the locations which the dI/dV spectra were taken wherein spectra at locations A through D were taken over clean graphene regions, while spectra at locations E through H were taken over PTCDA regions (60 nm×60 nm scan area, +1.0 V sample bias, 0.1 nA tunneling current).

FIG. 6B is a graph showing dI/dV spectra for graphene regions, with multiple spectra at each location indicated.

FIG. 6C is a graph showing dI/dV spectra for PTCDA regions.

FIGS. 7A-7J are differential tunneling conductance maps wherein STM topography images are shown in the top row (FIGS. 7A-7E), while dI/dV maps are shown in the bottom row (FIGS. 7F-7J) wherein the sample bias for each pair of topography and dI/dV images is indicated at the bottom of each image and wherein for all images, the scan area was 60 nm×60 nm, and the tunneling current setpoint was 0.1 nA.

FIG. 8A is an STM image of a PTCDA monolayer before ambient exposure (100 nm×100 nm scan area, -2.0 V sample bias, 0.05 nA tunneling current).

FIG. 8B is an STM image of a PTCDA monolayer after ambient exposure (80 nm×80 nm scan area, -1.5 V sample bias, 0.04 nA tunneling current).

FIG. 9A-9E illustrate feedback-controlled lithography (FCL) used to sequentially pattern four dots in a grid pattern in a PTCDA monolayer on epitaxial graphene wherein the FCL conditions were −4.0 V sample bias, 0.3 nA tunneling current, and 13% current cut-off and wherein, in all images, the scale bar is 15 nm and the tunneling conditions were −1.85 V sample bias, 0.04 nA tunneling current.

FIG. 10A is schematic illustration showing the deposition of the PTCDA monolayer on clean graphene, followed by patterning with the STM tip to reveal exposed graphene, and subsequent deposition of PTCDI-C8 into the patterned regions (not to scale).

FIG. 10B is an STM image of a PTCDA monolayer on epitaxial graphene (imaging conditions: −2.0 V sample bias, 0.03 nA tunneling current) wherein the scale bar is 10 nm.

FIG. 10C is an STM image after PTCDA was removed in two regions using FCL patterning of two rows of tightly spaced dots (FCL conditions: −4.6 V, 0.5 nA, 13% current trigger; imaging conditions: −2.1 V sample bias, 0.02 nA tunneling current) wherein the scale bar is 10 nm.

FIG. 10D is an STM image after PTCDI-C8 was deposited in situ, forming a well-ordered monolayer inside the patterned regions (imaging conditions: −1.8 V sample bias, 0.02 nA tunneling current) wherein the scale bar is 10 nm.

FIGS. 11A and 11B are AFM intermittent-contact topography images of (a) bare epitaxial graphene surface and (b) PTCDA-functionalized epitaxial graphene surface before ALD growth (all scale bars are 100 nm).

FIGS. 11C and 11D are AFM intermittent-contact topography images after growth of 2.5 nm of Al₂O₃ (25 ALD cycles), wherein the bare graphene sample shows uneven film growth (FIG. 11C), while the PTCDA-functionalized sample shows much smoother film growth (FIG. 11D) (all scale bars are 100 nm).

FIG. 11E is a graph showing ALD layer thickness as a function of ALD cycles for bare graphene, PTCDA-functionalized graphene, and SiO₂ control sample, as measured by ellipsometry.

FIG. 12A is a large area S™ image of PTCDI-C8 monolayer on epitaxial graphene (−2.0 V sample bias, 0.05 nA tunneling current, scale bar 20 nm).

FIG. 12B is a schematic showing the molecular structure of PTCDI-C8.

FIGS. 12C and 12D are high resolution images of PTCDI-C8 monolayer with one unit cell outlined in black. (−1.0 V (FIG. 12C) and +1.0 V (FIG. 12D) sample biases, 0.05 nA tunneling current, scale bar 5 nm).

### DESCRIPTION OF THE VARIOUS EMBODIMENTS

A room temperature molecular-resolution STM investigation of a self-assembled organic monolayer on epitaxial graphene is described. The organic semiconductor PTCDA was chosen for this study since it has been extensively studied as an archetypical system²⁸⁻³¹ for understanding organic thin fi1 ms³²⁻³⁴, and it exhibits ordered layer growth on various substrates such as silver³⁵⁻³⁸, gold³⁹⁻⁴¹, GaAs(100)⁴² and highly ordered pyrolytic graphite (HOPG)⁴³⁻⁴⁵. Furthermore, the recent work of Wang et al²³ used the carboxylic acid derivative of PTCDA to functionalize mechanically exfoliated graphene in order to introduce reactive sites for atomic layer deposition of Al₂O₃.

Room temperature self-assembly of PTCDA molecules on epitaxial graphene into stable, well-ordered monolayers that are arranged in a herringbone phase with extended domains spanning hundreds of nanometers is provided. In addition, the PTCDA monolayer is unperturbed by surface defects including atomic steps in the SiC substrate, the (6√3×√3)R30° interface layer, and point and line defects in the epitaxial graphene. Scanning tunneling spectroscopy (STS) performed on the PTCDA monolayers reveals strong features in the electronic density of states that are distinct from the pristine graphene regions. Overall, this study reveals conditions for forming robust, uniform, self-assembled organic monolayers on epitaxial graphene, thus setting the stage for the fabrication of graphene-based molecular electronic and sensing devices and the use of self-assembled monolayers as a template for further chemistry or materials deposition on graphene.

Epitaxial Graphene

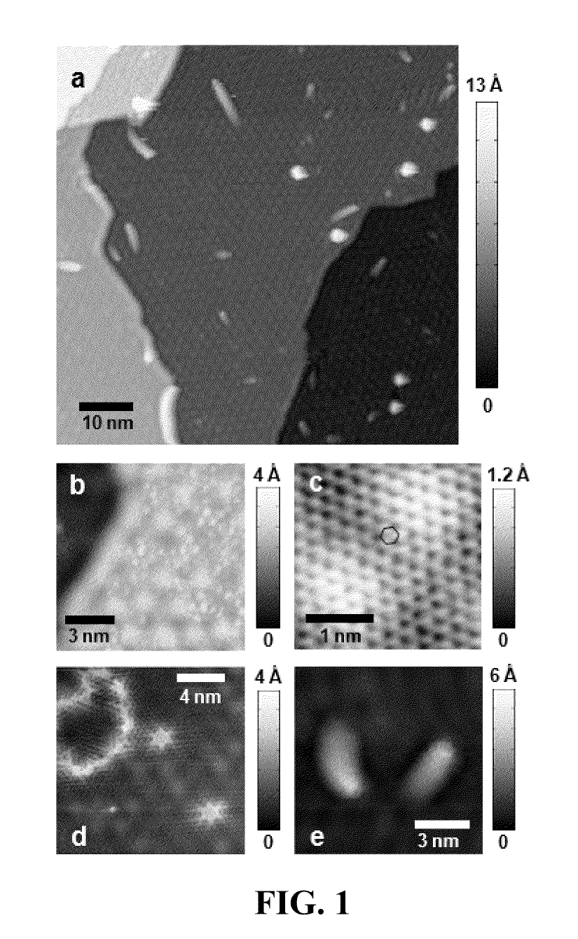

Epitaxial graphene prepared by graphitization of the SiC(0001) surface is shown in the room temperature STM image of FIG. 1a. A large terrace of monolayer graphene appears in the center of the image along with a few scattered defects. FIG. 1b shows a high resolution image of monolayer graphene, where the underlying (6√3×6√3)R30° phase is partially visible through the carbon lattice. A small area of bilayer graphene is shown with atomic resolution in FIG. 1c. The honeycomb atomic structure is indicated by the hexagon overlaid on the image. The inequivalent appearance of adjacent atoms results from the ABAB Bernal stacking between the two graphene sheets.¹⁵ Similar to a previous report²², the following three types of graphene defects are observed: six-fold scattering centers (FIG. 1d), loops formed by the nucleation of scattering centers (FIG. 1d), and subsurface nanotubes (FIG. 1e). We observed that annealing the epitaxial graphene at 1000° C. for several hours reduces the concentration of loop defects while the concentration of other types of defects remains unchanged.

Molecular Ordering

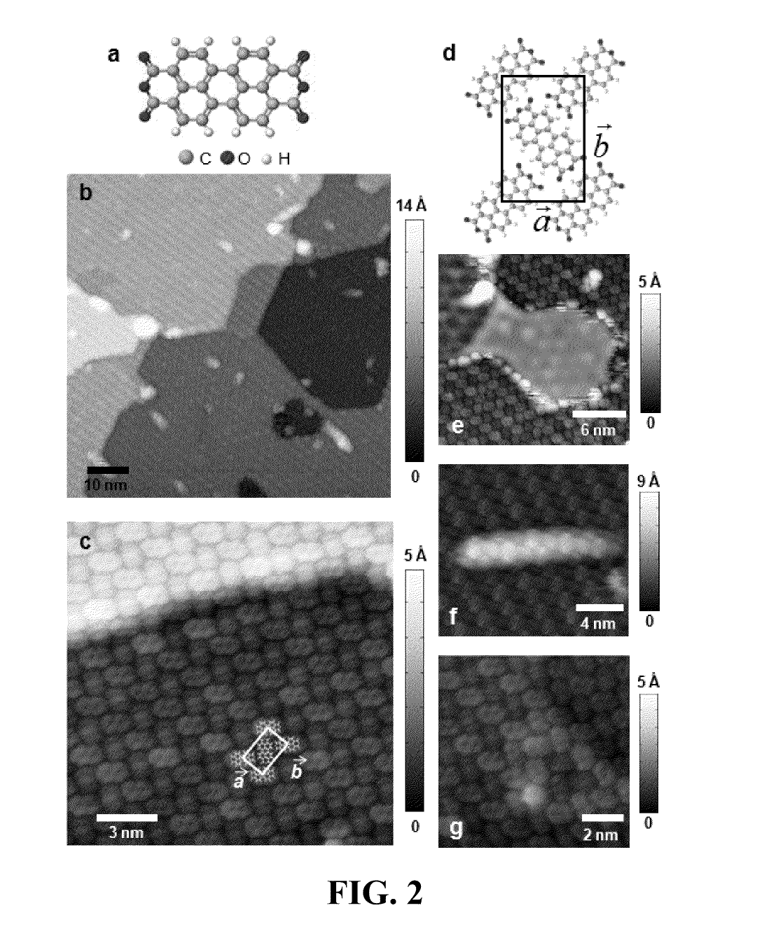

The PTCDA molecular structure is shown in FIG. 2a. PTCDA is a planar molecule based on a perylene backbone with a conjugated π-electron system and carboxylic acid anhydride side groups. Following gas-phase deposition in ultra-high vacuum (UHV), the resulting monolayer of PTCDA on graphene is observed in the room temperature STM image of FIG. 2b. The molecule forms a well-ordered, self-assembled monolayer with large domains that span hundreds of nanometers. In FIG. 2b, the same domain extends over the entire image, which includes several different steps of varying heights. FIG. 2c shows the PTCDA monolayer in higher resolution, revealing a herringbone pattern formed by the molecules. A herringbone pattern has been observed for PTCDA deposited on other substrates such as Ag(111)³⁵, Au(111)³⁹ and HOPG⁴³⁻⁴⁵. This structure closely resembles the (102) plane of the PTCDA bulk crystal structure²⁸. Molecular structure diagrams are drawn over the STM image in FIG. 2c to indicate the locations of molecules in the monolayer, and one unit cell outline is shown with the lattice vectors \vec{a} and \vec{b} specified. A larger schematic of the monolayer unit cell is shown in FIG. 2d. Molecules at the corner sites of the unit cell appear topographically higher under these tunneling conditions, leading to the appearance of parallel stripes of brighter and darker molecules running parallel to the \vec{a} direction as observed in the large-area S™ image of FIG. 2b.

The interaction of the PTCDA monolayer with various types of epitaxial graphene defects is shown in FIGS. 2c and 2e-g. The behavior of PTCDA at a step edge is shown in FIG. 2c. In this case, since a continuous sheet of graphene is growing over an atomic step in the underlying SiC substrate, the PTCDA monolayer follows the graphene and continuously flows over the step. On the other hand, when the graphene covering the two SiC steps are two separate sheets, the PTCDA monolayer is unable to continuously form over both, as observed in FIG. 2e. The PTCDA monolayer also continuously flows over the subsurface nanotube defects which are covered by a continuous sheet of graphene, as seen in FIG. 2f. The sixfold scattering center defects are difficult to detect under the PTCDA monolayer, but could potentially be the explanation for the bright protrusions observed underneath continuous PTCDA regions (FIG. 2g). These point defects do not perturb the ordering of the PTCDA monolayer.

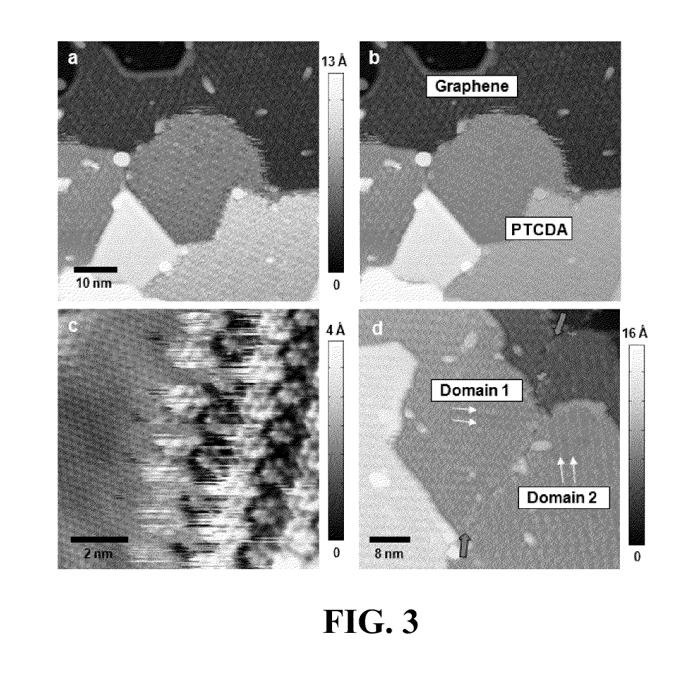

Submonolayer coverage of PTCDA results in the formation of stable, isolated molecular islands that exhibit the same herringbone arrangement as the full monolayer. In FIG. 3a, a large island of PTCDA is observed in the bottom right portion of the STM image, while the rest of the image is clean graphene. The PTCDA island is shaded blue in FIG. 3b to guide the eye. While the islands themselves are stable, their edges show instability that may be due to thermal motion of the molecules combined with interactions with the tip as it scans over the island boundaries. The high resolution STM image of FIG. 3c provides a clear view of the boundary of an island. The underlying graphene substrate is imaged with atomic resolution on the left side of the image, while the unstable region of the molecular island boundary is on the right side of the image. Despite this instability, the orientation of the molecules is still observable, and when compared to the atomically resolved adjacent graphene, it is apparent that the molecules are not aligned along one of the high-symmetry directions of the substrate. The lack of alignment with the graphene substrate is also shown by the long domain boundary in FIG. 3d, which is indicated by the large blue arrows. The \vec{a} vectors of the two domains are indicated by the thin white arrows, which form an angle of approximately 102° with respect to each other.

The stability and robustness of the PTCDA monolayer is further demonstrated by molecular-resolution STM imaging of the monolayer after removal from UHV (see Supporting Information). Following exposure to ambient conditions in the laboratory room, the monolayer maintains its ordering, and minimal surface contamination is observed.

Scanning Tunneling Spectroscopy

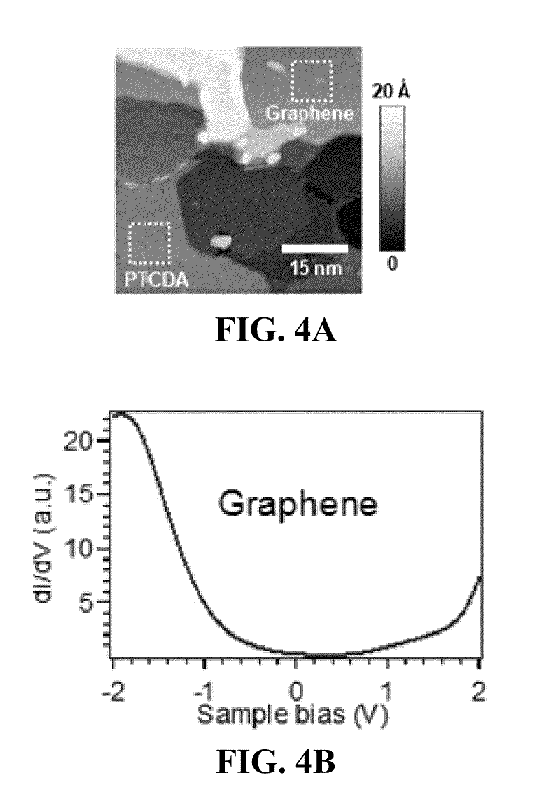

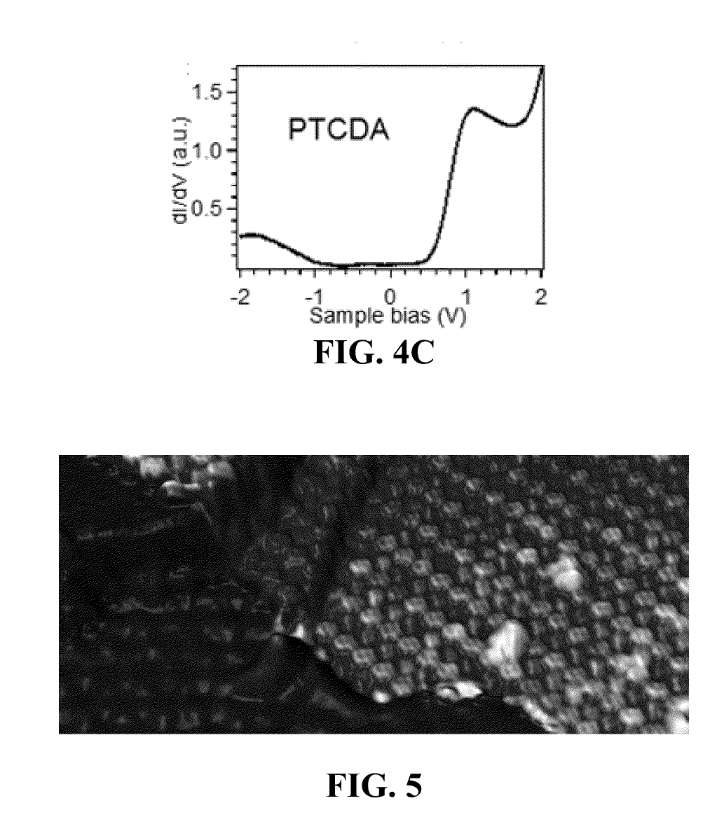

Scanning tunneling spectroscopy was performed to characterize the electronic properties of the PTCDA monolayer. An area of the sample that contained both PTCDA and pristine graphene was chosen (FIG. 4A). The differential tunneling conductance (dI/dV), which is correlated with the electronic density of states of the sample, was measured as a function of sample bias voltage for the clean graphene and PTCDA regions as shown in FIGS. 4B and 4C, respectively. These dI/dV curves were obtained by averaging many individual spectra acquired at random locations within the two square areas outlined in FIG. 4A, which both occur on regions of bilayer graphene.

The dI/dV curve for clean graphene (FIG. 4b) features high differential tunneling conductance at high positive and negative sample biases, and low differential tunneling conductance at low bias. In contrast, the dI/dV curve for PTCDA (FIG. 4c) possesses a large peak at approximately 1.1 V and a smaller peak at −1.8 V. The differential tunneling conductance is approximately zero between about 0.5 V and −1.0 V, and increases at higher biases.

The scanning tunneling microscopy and spectroscopy results presented above provide insight to the nature of the chemical interaction between the PTCDA molecules and the graphene sheets. The herringbone arrangement of the PTCDA monolayer is similar to the herringbone arrangement seen on other inert substrates including graphite and is also similar to the bulk structure of PTCDA. Consequently, it can be concluded that the interaction between the PTCDA and the graphene is relatively weak compared to the interaction between molecules. Additional evidence for the primary role of molecule-molecule interactions is the observation of instabilities at molecular domain boundaries where adjacent molecules are not present to stabilize the monolayer. The herringbone structure is stabilized by hydrogen bonding and quadrupolar interactions between adjacent molecules⁴⁵, while π-π* interactions bind the molecules to the graphene surface.

Despite the similar herringbone arrangement, many differences exist between PTCDA on epitaxial graphene compared to bulk graphite. While adjacent domains for PTCDA on HOPG have been observed to be rotated by multiples of 60° in previous studies^{43,44,46}, systematic rotations between domain boundaries are not detected on epitaxial graphene, leading to seemingly arbitrary rotations such as the 102° boundary shown in FIG. 2d. Also, several structural defects are seen in epitaxial graphene, which are not present in graphite, such as the subsurface nanotubes and SiC steps that are covered smoothly by the topmost layer of graphene. The PTCDA monolayer as described herein is unaffected by these defects, and is able to form continuously anywhere that the graphene sheet is uninterrupted. In fact, the PTCDA monolayer has fewer defects than the underlying epitaxial graphene. A similar mode of interaction is theoretically predicted for aromatic molecules on graphene, where π-π* attractive forces between the molecule and the graphene and hydrogen bonding between the molecules determine the ordering of the adsorbates⁴⁷. Ultimately, the insensitivity of the surface chemistry to the defects in epitaxial graphene implies that uniform self-assembled monolayers can be readily formed on epitaxial graphene surfaces, thus presenting a chemically uniform surface for subsequent chemistry or materials deposition.

The scanning tunneling spectroscopy results reveal distinct differences between the electronic structure of the PTCDA monolayer and pristine epitaxial graphene. For the PTCDA dI/dV curve, the peaks centered at 1.1 V and −1.8 V can likely be attributed to the LUMO and HOMO levels of the PTCDA molecule, respectively. These results are comparable to previous STS studies of PTCDA monolayers on gold substrates^{40,41,48}, where the LUMO level is reported between 0.9 V to 1.3 V, and the HOMO level is reported at approximately −1.9 V. Similarly, for PTCDA on HOPG, these two peaks in the dI/dV are measured at 0.7 V and −1.5 V, respectively⁴⁵. The subtle differences in peak positions can be attributed to variations in the setpoint tunneling conditions of the different experiments, as well as the work functions of the different substrates. The electronic properties of the PTCDA monolayer are distinct from those of the underlying graphene substrate, and appear to be largely unperturbed by the electronic properties of the epitaxial graphene. These results reinforce the earlier conclusion that PTCDA weakly interacts with the underlying graphene substrate, thus yielding insensitivity to surface defects.

The scanning tunneling spectroscopy results do not show strong evidence of surface transfer doping in the graphene due to the presence of the PTCDA monolayer. Since the previous low temperature STM study revealed that PTCDA yields a subtle n-type doping effect that is on the order of thermal energy at room temperature,₂₇ it is reasonable to expect that surface transfer doping will not be prominent at room temperature in this case.

Overall, despite the differences distinguishing epitaxial graphene from exfoliated graphene and graphite, particularly the presence of surface defects and the underlying SiC substrate, the self-assembly of PTCDA monolayers closely resembles the behavior that has been previously established on bulk graphite. Furthermore, characterization of the electronic structure of the PTCDA monolayer suggests that the molecule is not substantially perturbed by the electronic structure of epitaxial graphene or the underlying SiC substrate. Consequently, these results suggest that well-ordered, self-assembled monolayers should be readily achievable on epitaxial graphene for the diverse range of adsorbates that have been previously shown to form monolayers on graphite and related inert surfaces. The extensive body of work exploring the self-assembly of molecules on graphite surfaces should serve as a guide to future studies of self-assembly chemistry on epitaxial graphene. Furthermore, the stability of the PTCDA monolayer upon exposure to ambient conditions suggests opportunities for additional chemistries that can be performed outside of the UHV chamber.

A room temperature molecular-resolution STM study of a self-assembled organic monolayer on epitaxial graphene. PTCDA is shown to self-assemble into stable, well-ordered islands and monolayers with a herringbone arrangement at room temperature that closely resemble the formation on graphite. The PTCDA structures follow the graphene continuously over substrate step edges and other point and line surface defects. At full monolayer coverage, the defect-free molecular domains span hundreds of nanometers, while a submonolayer coverage yields stable, isolated molecular islands. Scanning tunneling spectroscopy results indicate that the electronic structure of the PTCDA monolayer is distinct and largely decoupled from that of the epitaxial graphene or underlying SiC substrate. These results demonstrate that organic functionalization of epitaxial graphene possesses wide tolerance and can be readily achieved at room temperature using surface chemistry that is analogous to bulk graphite. This well-ordered, stable, robust, nearly defect-free monolayer presents opportunities for exploring self-assembly chemistry on graphene, tailoring the chemical functionality of graphene, and templated growth and deposition of other materials as a potential route toward realizing graphene-based molecular electronic and sensing devices.

### EXPERIMENTAL

The practice of this invention can be further understood by reference to the following examples, which are provided by way of illustration only are not intended to be limiting.

Methods

Sample Preparation

The sample preparation and STM imaging were conducted in a custom-built UHV STM system with separate sample preparation and imaging chambers operating at room temperature and a base pressure of 5×10⁻¹¹ torr⁴⁹. The 6H-SiC(0001) n-type substrates (Cree, Inc.) were degreased in acetone and isopropanol before being introduced into the vacuum chamber, where they were outgassed overnight at 600° C. The surface was graphitized by annealing the substrate at 1250° C. for several cycles of 30 s. The substrate was then annealed at 1000° C. for 2-3 hours and cooled to room temperature before molecular deposition or S™ imaging. The cleanliness of the graphene surface was verified by STM imaging, which revealed a mixture of monolayer and bilayer graphene, as well as occasional patches of the (6√3×√3)R30° phase. The substrate was kept at room temperature during molecular deposition and subsequent STM imaging. The PTCDA (97% purity, Sigma-Aldrich) was placed into an alumina-coated W boat and outgassed overnight in the UHV chamber. To deposit the PTCDA onto graphene, the boat was resistively heated to generate a steady molecular flux into which the clean graphene surface was introduced. The PTCDA coverage was controlled by timing the exposure and calibrating the coverage by STM imaging. To remove the PTCDA monolayers, the sample was annealed at 600° C. to recover clean graphene.

STM and STS

Topographic STM imaging was conducted in constant current mode with the bias voltage applied to the sample. Both electrochemically etched W tips and commercially available PtIr tips (Agilent Technologies) were used. Scanning tunneling spectroscopy was conducted by the lock-in detection method, where a small periodic modulation (0.04 V_{RMS}, 7.5 kHz) was applied to the sample bias and the tunneling current response was measured with a lock-in amplifier (Stanford Research Systems) to obtain the differential tunneling conductance (dI/dV). Spectroscopic data in the form of dI/dV vs. V curves were measured by freezing both the tip motion and tunneling feedback followed by sweeping the applied sample bias. Many curves taken at randomly selected spatial locations were averaged to obtain the curves shown in FIG. 4 (see below).

Scanning Tunneling Spectroscopy of PTCDA and Graphene

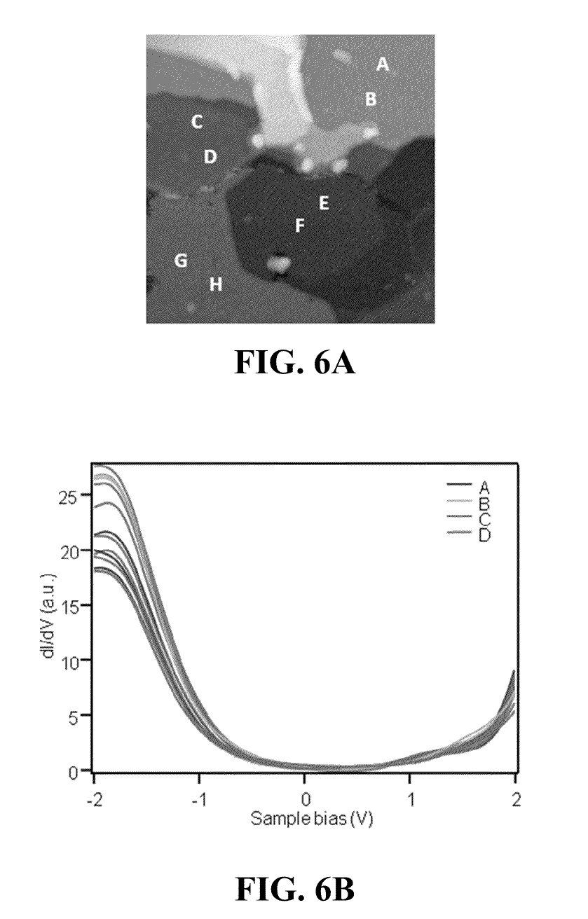

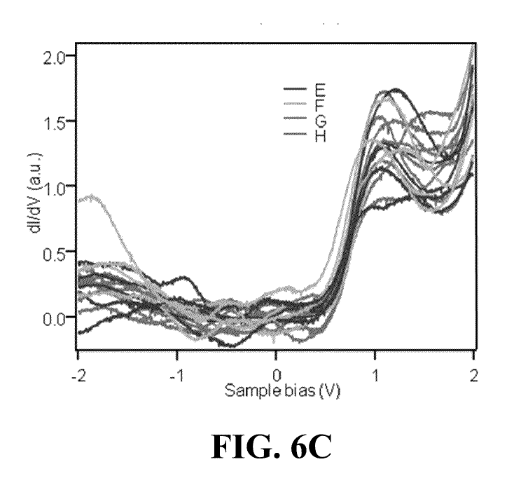

Scanning tunneling spectroscopy (STS) was performed to characterize the electronic structure of the PTCDA monolayer and the graphene substrate. Differential tunneling conductance (dI/dV vs. V) curves were obtained over many locations as indicated by the markers in the STM topography image of FIG. 6A, which contains a region of clean graphene and a region of PTCDA. The dI/dV spectra are shown in FIGS. 6B and 6C for the graphene and PTCDA regions, respectively. The spectra vary slightly from curve to curve but have the same general features.

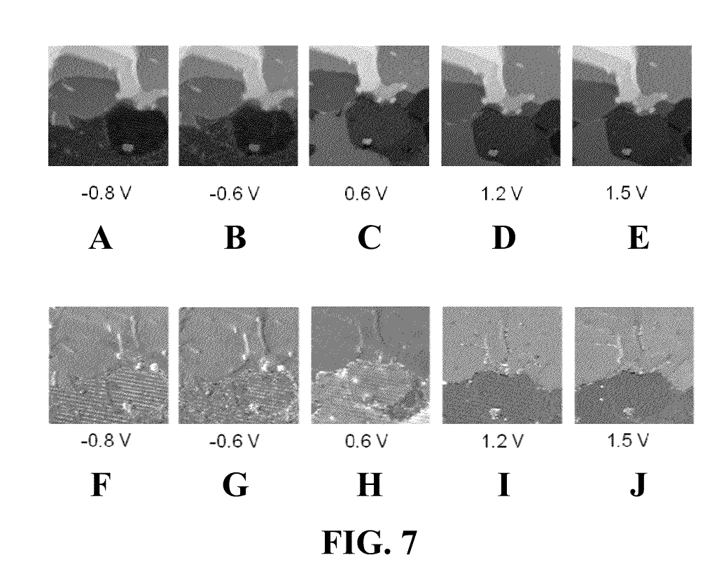

The electronic properties were spatially mapped by simultaneously taking dI/dV images and topographic images at various sample biases. FIG. 7 shows the STM topography images in the top row and the dI/dV maps in the bottom row. The color scalings of the dI/dV maps have been adjusted to enhance contrasts within each individual image rather than maintaining the same scaling across all images. The dI/dV maps support the main findings from the dI/dV spectra. The electronic features of the graphene regions and PTCDA regions are fairly uniform but are distinct from each other, and there are no prominent edge effects at the PTCDA boundaries. At sample biases of −0.8 V and −0.6 V, we can see in the dI/dV maps that the graphene and PTCDA regions have comparable dI/dV magnitudes, in agreement with the dI/dV spectra. Stronger contrast between the two regions is observed at 0.6 V, 1.2, and 1.5 V. At 0.6 V, the PTCDA region appears brighter than the graphene region, while at 1.2 V and 1.5 V the contrast is reversed, correlating with the changes in magnitudes of the dI/dV spectra at those biases in FIGS. 6B and 6C. Slight spatial modulations in dI/dV within the PTCDA regions are also seen, perhaps contributing to the increased variations between dI/dV spectra for PTCDA compared to those for graphene.

Stability and Robustness of the PTCDA Monolayer

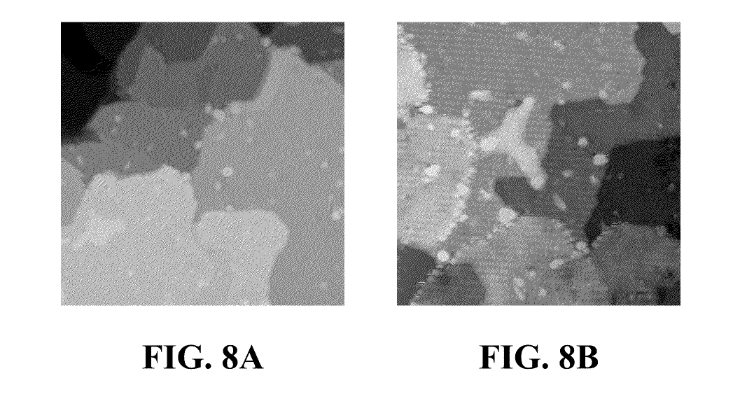

The stability and robustness of the PTCDA monolayer on epitaxial graphene was demonstrated by removing the PTCDA-covered substrate from the UHV chamber into ambient conditions. The initial PTCDA monolayer after UHV deposition is shown in the STM image of FIG. 8A. The sample was moved from the UHV chamber into a separately pumped load lock chamber, which was then pressurized to atmospheric pressure with ultrapure nitrogen gas. The load lock was then opened, and the sample was moved into the laboratory room (i.e., ambient conditions) for several minutes before being returned to the load lock. The load lock was then pumped down from atmospheric pressure to high vacuum conditions by a turbomolecular pump for two hours before the sample was brought into the UHV chamber. The sample was indirectly degassed by pressing two copper blocks onto the sides of the sample holder, which were then heated to ˜100° C. for several hours. After this treatment, the sample was imaged with the STM, which showed intact PTCDA monolayers with a slight increase in the defect concentration (FIG. 8B). The load lock pressurization and pump-down procedures did not result in significant damage to the monolayer, and the time spent in ambient conditions led to minimal contamination of the surface.

As described below, the PTCDA monolayer can be patterned with nanoscale precision by selectively removing portions of the monolayer using the ultrahigh vacuum (UHV) scanning tunneling microscope (STM). The patterned monolayer can act as a chemical resist against deposition of additional molecules, which only form monolayers in regions that have been cleared of PTCDA. As also described below, the PTCDA monolayer has also been used to seed the atomic layer deposition (ALD) growth of smooth metal oxide dielectric layers, which do not grow uniformly on bare graphene. Well-ordered self-assembled monolayers on epitaxial graphene of other perylene derivatives including N,N′-dioctyl-3,4,9,10-perylenedicarboximide (PTCDI-C8) are also described below.

Nanopatterning PTCDA with UHV STM

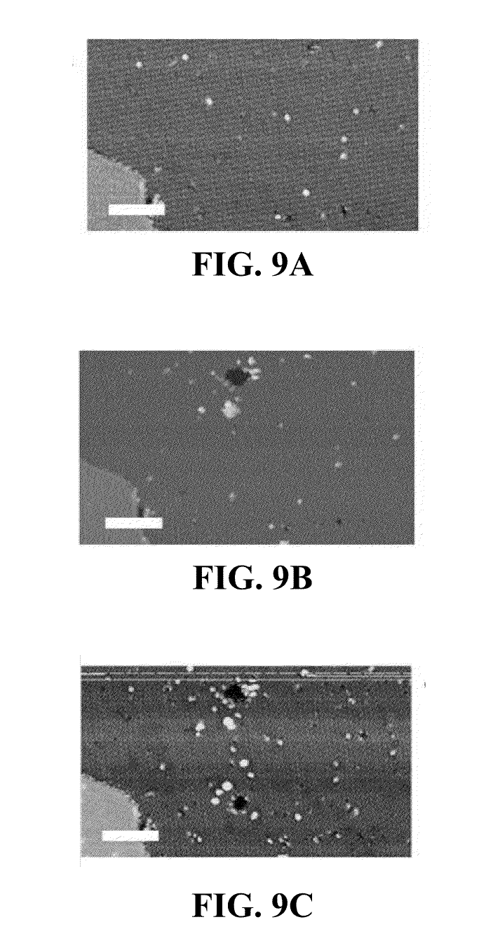

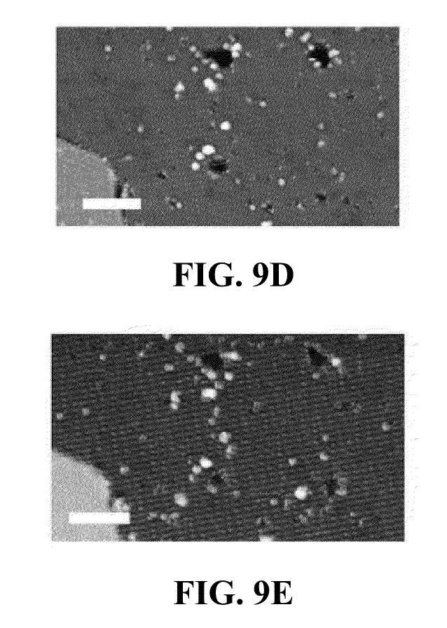

Controllable modification of the surface chemistry of graphene with high spatial resolution can be used for various applications such as electronic devices and chemical sensors. Portions of the PTCDA monolayer were controllably removed to expose clean regions of unfunctionalized graphene by applying enhanced tunneling conditions (higher tunneling current and more negative sample bias) between the tip and sample. To enhance the control and reproducibility of patterning, we used the method of feedback-controlled lithography (FCL),₅₁ in which successful patterning events are detected by a second feedback loop to control the extent of PTCDA molecules that are removed. FIG. 9 shows STM images of an array of sub-5 nm dots formed step by step using FCL. In this way, arbitrary nanoscale patterns in the PTCDA monolayer can be created, thus tailoring the local surface chemistry of the epitaxial graphene.

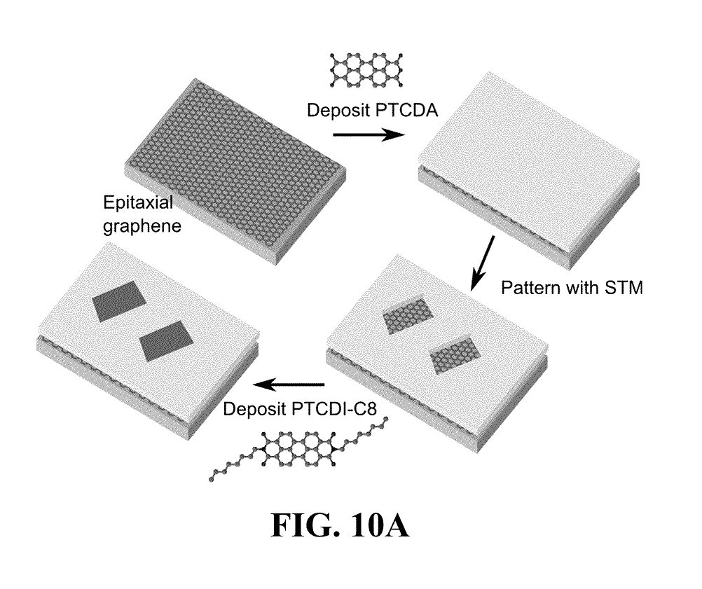

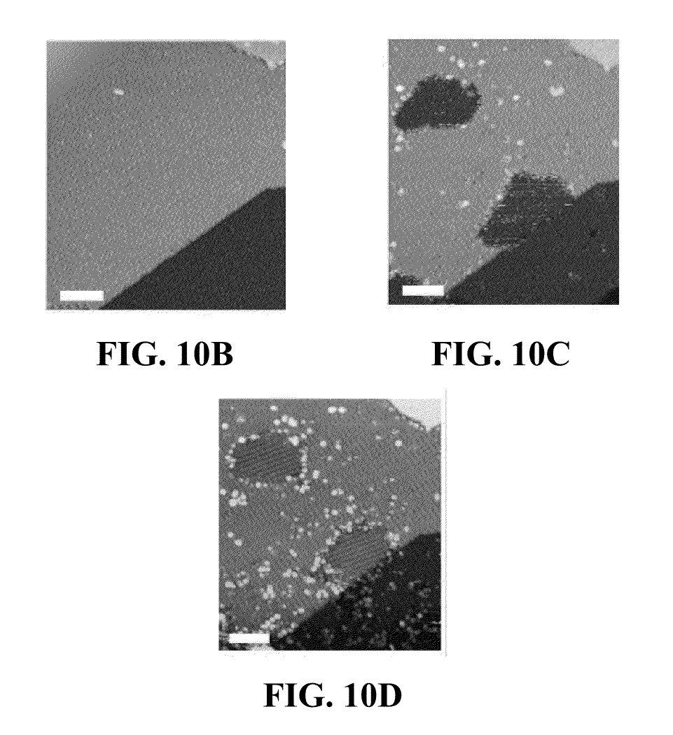

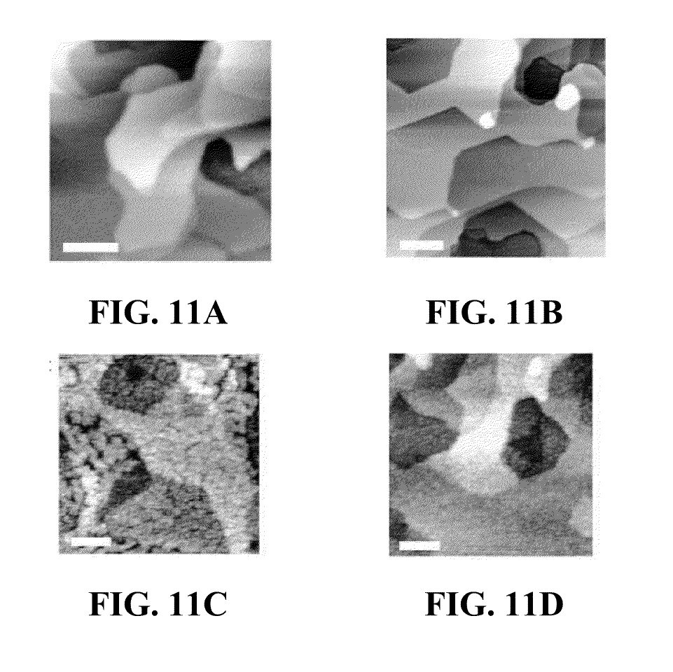

In addition to the local chemical modification by removal of PTCDA, further modification steps can be taken by applying the patterned PTCDA monolayer as a chemical resist. To demonstrate this application, PTCDI-C8 was deposited onto the sample after patterning of PTCDA. The PTCDI-C8 molecules formed a monolayer only in the regions that had been cleared of PTCDA. This process of patterning and deposition is illustrated schematically in FIG. 10A. The STM images in FIG. 10 show the sample after PTCDA monolayer formation (FIG. 10B), after formation of two patterns by STM FCL of two rows of tightly spaced dots (FIG. 10C), and after deposition of PTCDI-C8 (FIG. 10D). The PTCDI-C8 forms a distinct monolayer only inside the patterned regions where clean graphene was revealed when the PTCDA was removed.

Seeding Layer for Atomic Layer Deposition of Metal Oxides

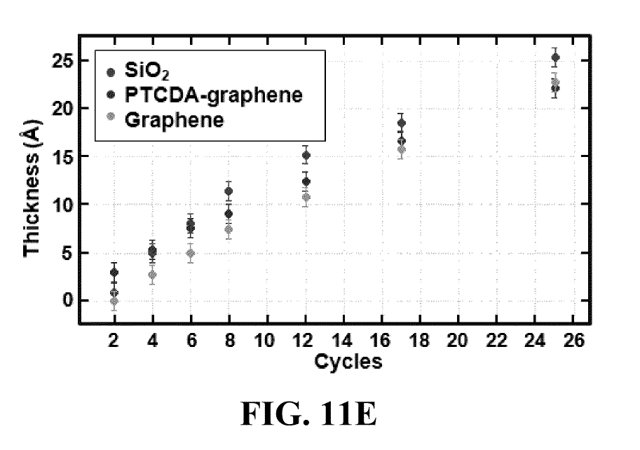

The growth of high-k dielectric thin films is crucial for the fabrication of electronic devices. For graphene-based devices, the challenge is the chemical inertness of the graphene sheet which hinders the nucleation and growth of such materials. We have used the PTCDA monolayer on epitaxial graphene as a seeding layer for the uniform growth of metal oxide thin films. The atomic force microscope (AFM) topography images in FIG. 11 show the growth of Al₂O₃ films using atomic layer deposition (ALD) on bare epitaxial graphene and epitaxial graphene functionalized with a PTCDA monolayer. While the bare and functionalized surfaces appear quite similar before film growth (FIGS. 11A and 11B), the film surfaces after 2.5 nm of Al₂O₃ growth are noticeably different. The growth on the bare graphene surface results in a rough, inhomogeneous film, whereas growth on the PTCDA-seeded surface produced a conformal and uniform film. While not wishing to be bound by theory, the oxygen on the periphery of the PTCDA molecule may act as nucleation sites for the ALD reaction. Although Al₂O₃ is disclosed, any metal oxide may be used. Exemplary metal oxides include, but are not limited to, Al₂O₃, HfO₂ and ZnO.

The ALD growth results demonstrate the robustness of the PTCDA monolayer under ambient conditions, intermittent-contact mode AFM imaging, and elevated reaction conditions. It also suggests that other chemistry (e.g., biofunctionalization) can be templated by perylene-based monolayers, thus presenting opportunities for graphene-based molecular electronic and sensing technologies.

Other Organic Monolayers on Graphene

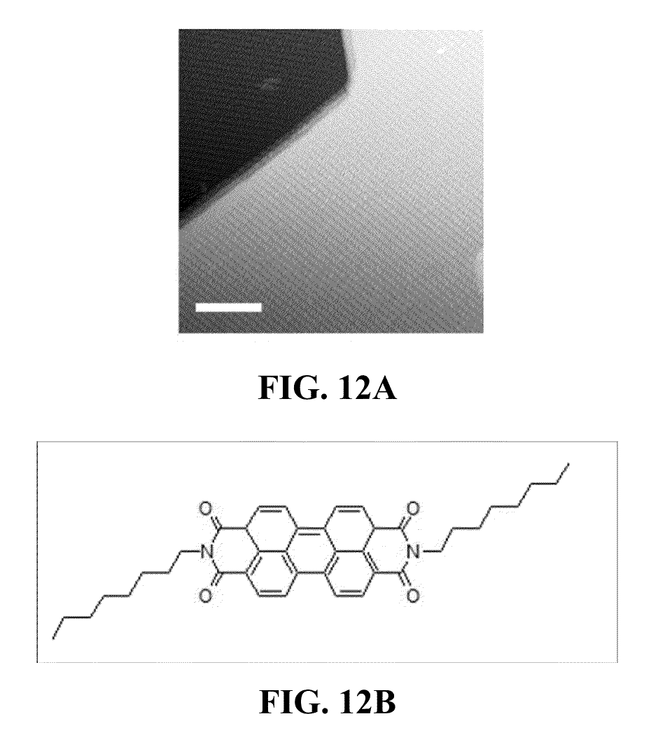

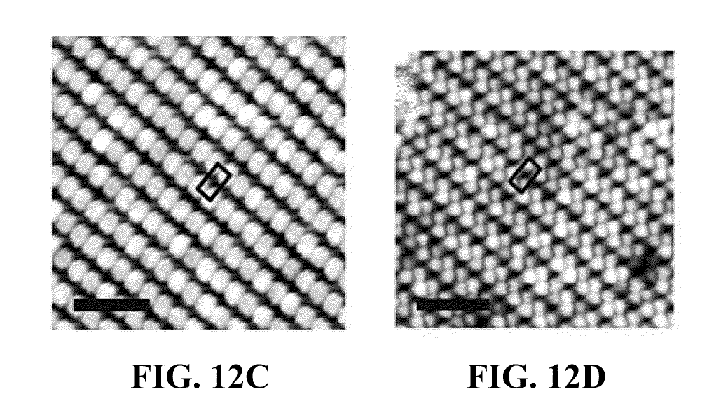

To expand the chemical functionality of the self-assembled monolayers on graphene, monolayers of additional perylene derivatives have been made. For example, monolayers of N,N′-dioctyl-3,4,9,10-perylenedicarboximide (PTCDI-C8) have been formed on epitaxial graphene at room temperature via thermal evaporation. The PTCDI-C8 molecule, whose structure is illustrated in FIG. 12B, has the same perylene-based backbone as PTCDA, but it has nitrogen atoms and eight-carbon alkyl chains that change the molecular ordering. Unlike the herringbone arrangement of PTCDA, a rectangular arrangement was observed in the monolayer, as shown in FIG. 12. In addition, long-range ordering was observed as seen in the large-area S™ image in FIG. 12A. The molecular resolution STM images in FIGS. 12C and 12D show how the unit cell of the PTCDI-C8 monolayer differs from that of PTCDA. While not wishing to be bound by theory, it is believed that the PTCDI-C8 molecules interact with the graphene surface via non-covalent π-π* interactions, similar to the interaction of PTCDA with graphene. However, the additional side groups modify the intermolecular interactions as compared to PTCDA and result in a different surface arrangement.

A wide range of polycyclic aromatic molecules are expected to interact non-covalently with epitaxial graphene to form ordered monolayers. These molecules can be modified with a variety of functional groups, thus greatly increasing the chemical functionalities that can be imparted to graphene.

While the foregoing specification teaches the principles of the present invention, with examples provided for the purpose of illustration, it will be appreciated by one skilled in the art from reading this disclosure that various changes in form and detail can be made without departing from the true scope of the invention.

### REFERENCES

[1] Geim, A. K. and Novoselov, K. S. The rise of graphene. Nature Mater. 6, 183-191 (2007).
[2] Katsnelson, M. I., Novoselov, K. S., and Geim, A. K. Chiral tunnelling and the Klein paradox in graphene. Nature Phys. 2, 620-625 (2006).
[3] Novoselov, K. S. et al. Two-dimensional gas of massless Dirac fermions in graphene. Nature 438, 197-200 (2005).
[4] Novoselov, K. S. et al. Unconventional quantum Hall effect and Berry's phase of 2 pi in bilayer graphene. Nature Phys. 2, 177-180 (2006).
[5] Berger, C. et al. Ultrathin epitaxial graphite: 2D electron gas properties and a route toward graphene-based nanoelectronics. J. Phys. Chem. B108, 19912-19916 (2004).
[6] Berger, C. et al. Electronic confinement and coherence in patterned epitaxial graphene. Science 312, 1191-1196 (2006).
[7] de Heer, W. A. et al. Epitaxial graphene. Solid State Commun. 143, 92-100 (2007).
[8] Gu, G. et al. Field effect in epitaxial graphene on a silicon carbide substrate. Appl. Phys. Lett. 90, 253507 (2007).
[9] Kedzierski, J. et al. Epitaxial graphene transistors on SiC substrates. IEEE Trans. Electron Devices 55, 2078-2085 (2008).
[10] Bostwick, A., Ohta, T., Seyller, T., Horn, K., and Rotenberg, E. Quasiparticle dynamics in graphene. Nature Phys. 3, 36-40 (2007).
[11] Ohta, T., Bostwick, A., Seyller, T., Horn, K., and Rotenberg, E. Controlling the electronic structure of bilayer graphene. Science 313, 951-954 (2006).
[12] Zhou, S. Y. et al. Substrate-induced bandgap opening in epitaxial graphene. Nature Mater. 6, 770-775 (2007).
[13] Ni, Z. H. et al. Raman spectroscopy of epitaxial graphene on a SiC substrate. Phys. Rev. B 77, 115416 (2008).
[14] Brar, V. W. et al. Scanning tunneling spectroscopy of inhomogeneous electronic structure in monolayer and bilayer graphene on SiC. Appl. Phys. Lett. 91, 122102 (2007).
[15] Lauffer, P. et al. Atomic and electronic structure of few-layer graphene on SiC(0001) studied with scanning tunneling microscopy and spectroscopy. Phys. Rev. B 77, 155426 (2008).
[16] Poon, S. W., Chen, W., Tok, E. S., and Wee, A. T. S. Probing epitaxial growth of graphene on silicon carbide by metal decoration. Appl. Phys. Lett. 92, 104102 (2008).
[17] Riedl, C., Starke, U., Bernhardt, J., Franke, M., and Heinz, K. Structural properties of the graphene-SiC(0001) interface as a key for the preparation of homogeneous large-terrace graphene surfaces. Phys. Rev. B 76, 245406 (2007).
[18] Rutter, G. M. et al. Scattering and interference in epitaxial graphene. Science 317, 219-222 (2007).
[19] Rutter, G. M. et al. Imaging the interface of epitaxial graphene with silicon carbide via scanning tunneling microscopy. Phys. Rev. B 76, 235416 (2007).
[20] Mallet, P. et al. Electron states of mono- and bilayer graphene on SiC probed by scanning-tunneling microscopy. Phys. Rev. B 76, 041403 (2007).
[21] Seyller, T. et al. Structural and electronic properties of graphite layers grown on SiC(0001). Surf. Sci. 600, 3906-3911 (2006).
[22] Guisinger, N. P. et al. Atomic-scale investigation of graphene formation on 6H-SiC(0001). J. Vac. Sci. Technol. A 26, 932-937 (2008).
[23] Wang, X. R., Tabakman, S. M., and Dai, H. J. Atomic layer deposition of metal oxides on pristine and functionalized graphene. J. Am. Chem. Soc. 130, 8152-8153 (2008).
[24] Chen, W., Chen, S., Qi, D.C., Gao, X. Y., and Wee, A. T. S. Surface transfer p-type doping of epitaxial graphene. J. Am. Chem. Soc. 129, 10418-10422 (2007).
[25] Chen, J. H. et al. Charged-impurity scattering in graphene. Nature Phys. 4, 377-381 (2008).
[26] Gierz, I., Riedl, C., Starke, U., Ast, C. R., and Kern, K. Atomic Hole Doping of Graphene. Nano Lett. 8, 4603-4607 (2008).
[27] Lauffer, P., Emtsev, K. V., Graupner, R., Seyller, T., and Ley, L. Molecular and electronic structure of PTCDA on bilayer graphene on SiC(0001) studied with scanning tunneling microscopy. Phys. Status Solidi B 245, 2064-2067 (2008).
[28] Forrest, S. R. Ultrathin organic films grown by organic molecular beam deposition and related techniques. Chem. Rev. 97, 1793-1896 (1997).
[29] Forrest, S. R. Organic-inorganic semiconductor devices and 3, 4, 9, 10 perylenetetracarboxylic dianhydride: an early history of organic electronics. J. Phys.: Condens. Matter 15, S2599-S2610 (2003).
[30] Tautz, F. S. Structure and bonding of large aromatic molecules on noble metal surfaces: The example of PTCDA. Prog. Surf. Sci. 82, 479-520 (2007).
[31] Hirose, Y. et al. Chemistry and electronic properties of metal-organic semiconductor interfaces: Al, Ti, In, Sn, Ag, and Au on PTCDA. Phys. Rev. B 54, 13748-13758 (1996).
[32] Shirota, Y. Organic materials for electronic and optoelectronic devices. J. Mater. Chem. 10, 1-25 (2000).
[33] Forrest, S. R. The path to ubiquitous and low-cost organic electronic appliances on plastic. Nature 428, 911-918 (2004).
[34] Dimitrakopoulos, C. D. and Malenfant, P. R. L. Organic thin film transistors for large area electronics. Adv. Mater. 14, 99-117 (2002).
[35] Eremtchenko, M., Schaefer, J. A., and Tautz, F. S. Understanding and tuning the epitaxy of large aromatic adsorbates by molecular design. Nature 425, 602-605 (2003).
[36] Rohlfing, M., Temirov, R., and Tautz, F. S. Adsorption structure and scanning tunneling data of a prototype organic-inorganic interface: PTCDA on Ag(111). Phys. Rev. B 76, 115421 (2007).
[37] Kraft, A. et al. Lateral adsorption geometry and site-specific electronic structure of a large organic chemisorbate on a metal surface. Phys. Rev. B 74, 041402 (2006).
[38] Glockler, K. et al. Highly ordered structures and submolecular scanning tunnelling microscopy contrast of PTCDA and DM-PBDCI monolayers on Ag(111) and Ag(110). Surf. Sci. 405, 1-20 (1998).
[39] Schmitz-Hithsch, T., Fritz, T., Sellam, F., Staub, R., and Leo, K. Epitaxial growth of 3,4,9,10-perylene-tetracarboxylic-dianhydride on Au(111): A S™ and RHEED study. Phys. Rev. B 55, 7972-7976 (1997).
[40] Nicoara, N., Roman, E., Gomez-Rodriguez, J. M., Martin-Gago, J. A., and Mendez, J. Scanning tunneling and photoemission spectroscopies at the PTCDA/Au(111) interface. Org. Electron. 7, 287-294 (2006).
[41] Toerker, M., Fritz, T., Proehl, H., Sellam, F., and Leo, K. Tunneling spectroscopy study of 3,4,9,10-perylenetetracarboxylic dianhydride on Au(100). Surf. Sci. 491, 255-264 (2001).
[42] Nicoara, N. et al. Scanning tunnelling microscopy and spectroscopy on organic PTCDA films deposited on sulfur passivated GaAs(001). J. Phys.: Condens. Matter 15, S2619-S2629 (2003).
[43] Hoshino, A., Isoda, S., Kurata, H., and Kobayashi, T. Scanning tunneling microscope contrast of perylene-3,4,9,10-tetracarboxylic-dianhydride on graphite and its application to the study of epitaxy. J. Appl. Phys. 76, 4113-4120 (1994).
[44] Kendrick, C., Kahn, A., and Forrest, S. R. STM study of the organic semiconductor PTCDA on highly-oriented pyrolytic. Appl. Surf. Sci. 104/105, 586-594 (1995).
[45] Ludwig, C., Gompf, B., Petersen, J., Strohmaier, R., and Eisenmenger, W. STM investigations of PTCDA and PTCDI on graphite and MoS2-A systematic study of epitaxy and STM image-contrast. Z. Phys. B: Condens. Matter 93, 365-373 (1994).
[46] Forrest, S. R., Burrows, P. E., Haskal, E. I., and So, F. F. Ultrahigh-vacuum quasiepitaxial growth of model van der Waals thin films. II. Experiment. Phys. Rev. B 49, 11309-11321 (1994).
[47] Rochefort, A. and Wuest, J. D. Interaction of substituted aromatic compounds with graphene. Langmuir 25, 210-215 (2009).
[48] Tsiper, E. V., Soos, Z. G., Gao, W., and Kahn, A. Electronic polarization at surfaces and thin films of organic molecular crystals: PTCDA. Chem. Phys. Lett. 360, 47-52 (2002).
[49] Foley, E. T., Yoder, N. L., Guisinger, N. P., and Hersam, M. C. Cryogenic variable temperature ultrahigh vacuum scanning tunneling microscope for single molecule studies on silicon surfaces. Rev. Sci. Instrum. 75, 5280-5287 (2004).
[50] Wang QH and Hersam MC. Room-temperature molecular-resolution characterization of self-assembled organic monolayers on epitaxial graphene. Nature Chemistry 1, 206-211 (2009).
[51] Hersam M C, Guisinger N P, and Lyding J W. Silicon-based molecular nanotechnology. Nanotechnology 11, 70-76 (2000).

What is claimed is:

1. An article of manufacture comprising:
an epitaxial graphene layer;
a monolayer of molecules on a surface of the graphene layer;
wherein the molecules are 3,4,9,10-perylene-tetracarboxylic dianhydride (PTCDA) molecules arranged in a herringbone phase and/or wherein the molecules are of the following formula: 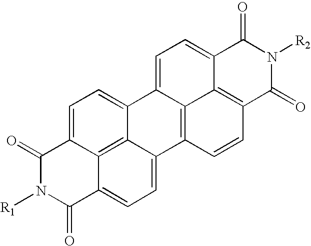
wherein R₁ and R₂ are alkyl groups.

2. The article of manufacture of claim 1, wherein the epitaxial graphene layer is formed on SiC(0001).

3. The article of manufacture of claim 1, wherein the molecules are N,N′-dioctyl-3,4,9,10-perylenedicarboximide (PTCDI-C8).

4. The article of manufacture of claim 1, wherein one or more regions of the monolayer are on the graphene surface such that portions of the graphene surface are exposed.

5. The article of manufacture of claim 4, further comprising one or more regions of a monolayer of second molecules different than the first molecules on the exposed surface of the graphene layer.

6. The article of manufacture of claim 5, wherein the first molecule is PTCDA and the second molecule is PTCDI-C8.

7. The article of manufacture of claim 1, further comprising a layer of a metal oxide on the monolayer.

8. The article of manufacture of claim 7, wherein the metal oxide is Al₂O₃, HfO₂ or ZnO.

9. The article of manufacture of claim 4, further comprising a layer of a metal oxide on the one or more regions of the monolayer.

10. The article of manufacture of claim 9, wherein the metal oxide is Al₂O₃, HfO₂ or ZnO.

11. A method comprising:
depositing a monolayer of molecules on a surface of an epitaxial graphene layer:
wherein the molecules are 3,4,9,10-perylene-tetracarboxylic dianhydride (PTCDA) molecules arranged in a herringbone phase or wherein the molecules are of the following formula: 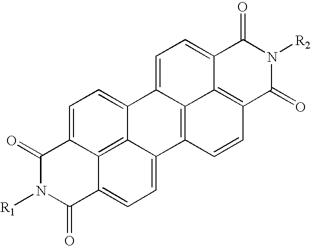
wherein R₁ and R₂ are alkyl groups.

12. The method of claim 11, wherein the molecules are N,N′-dioctyl-3,4,9,10-perylenedicarboximide (PTCDI-C8).

13. The method of claim 11, wherein depositing comprises contacting the molecules in a vapor phase with the surface of the graphene layer.

14. The method of claim 11, wherein the surface of the epitaxial layer is at a temperature of 20-25° C. during deposition.

15. The method of claim 14, wherein depositing comprises depositing under a pressure less than atmospheric pressure.

16. The method of claim 11, further comprising:
forming the epitaxial graphene layer on SiC(0001); and
optionally annealing the graphene layer before depositing the monolayer of molecules.

17. The method of claim 11, further comprising depositing a metal oxide on the monolayer.

18. The method of claim 11, further comprising selectively removing portions of the monolayer.

19. The method of claim 13, wherein selectively removing portions of the monolayer comprises using a scanning tunneling microscope (STM) to selectively remove portions of the monolayer thereby forming one or more regions of the monolayer on the graphene surface.

20. The method of claim 19, further comprising depositing a metal oxide on the one or more regions of the monolayer.
